(19) United States
(12) Patent Application Publication
(10) Pub. No.: US 2021/0375638 A1
(43) Pub. Date: Dec. 2, 2021

(54) SEMICONDUCTOR SUBSTRATE AND METHOD OF FORMING THE SAME

(71) Applicant: WAFER WORKS CORPORATION, Taoyuan City (TW)

(72) Inventors: Wen-Chung LI, Taoyuan City (TW); Tsui-Yun LIAO, Taoyuan City (TW)

(21) Appl. No.: 17/035,750

(22) Filed: Sep. 29, 2020

(30) Foreign Application Priority Data
Jun. 2, 2020 (TW) 109118389

(51) Int. Cl. H01L 21/322; H01L 21/20; H01L 21/02

(52) U.S. Cl. CPC H01L 21/3226; H01L 21/02164; H01L 21/20

(57) ABSTRACT

A semiconductor substrate includes a first silicon substrate, an oxide layer, a second silicon substrate, and an epitaxial layer. The oxide layer is disposed on the first silicon substrate. The second silicon substrate is disposed on the oxide layer. The second silicon substrate has a thickness between 10 nm and 10 μm. The epitaxial layer is disposed on the second silicon substrate.

### CROSS-REFERENCE TO RELATED APPLICATION

This application claims priority to Taiwan Application Serial Number 109118389, filed Jun. 2, 2020, which is herein incorporated by reference.

### BACKGROUND

### Field of Invention

The present disclosure relates to a semiconductor substrate and a method of forming a semiconductor substrate.

### Description of Related Art

With the advancement of the semiconductor integrated circuit (IC) industry, manufacturers need to optimize and improve the manufacturing process to produce products with smaller sizes and better performance. In the semiconductor manufacturing process, the performance of the substrate will affect the subsequent manufacturing process and the quality of IC products. For example, the silicon on insulator (SOI) substrate has the advantages of reducing leakage current, increasing saturation current, and low power consumption, and has been widely studied and applied.

In the process technology of using a silicon substrate to grow an epitaxial layer to form a semiconductor substrate, the crystal lattice defects of the epitaxial layer may cause stress to be concentrated on the silicon substrate. When the stress releases, a dislocation is generated in the epitaxial layer, thereby causing the silicon substrate to be deformed or twisted, or even broken. In addition, the epitaxial layer and the silicon substrate have a large difference in lattice constant, and the epitaxial layer and the silicon substrate also have a large difference in thermal expansion coefficient, which easily causes warpage of the semiconductor substrate and poor quality of the epitaxial layer.

In view of the above, there is an urgent need for a semiconductor substrate that can solve the above problems and a method for forming the semiconductor substrate.

### SUMMARY

The present disclosure provides a semiconductor substrate including a first silicon substrate, an oxide layer, a second silicon substrate, and an epitaxial layer. The oxide layer is disposed on the first silicon substrate. The second silicon substrate is disposed on the oxide layer. The second silicon substrate has a thickness between 10 nm and 10 μm. The epitaxial layer is disposed on the second silicon substrate.

In some embodiments, the first silicon substrate has a first resistance value, the second silicon substrate has a second resistance value, and the first resistance value is less than the second resistance value.

In some embodiments, the first silicon substrate has a first resistance value between 0.0001-1 Ohm-cm.

In some embodiments, the second silicon substrate has a second resistance value between 1-10000 Ohm-cm.

In some embodiments, the first silicon substrate has a first resistance value between 0.0001-1 Ohm-cm, and the second silicon substrate has a second resistance value between 1-10000 Ohm-cm.

In some embodiments, the first silicon substrate is a heavily doped chip.

In some embodiments, the epitaxial layer includes gallium nitride, gallium phosphide, gallium arsenide, indium phosphide, indium gallium phosphide, indium gallium antimonide, or a combination thereof.

The present disclosure provides a method of forming a semiconductor substrate including the following operations. A composite substrate is received. The composite substrate includes a first silicon substrate, an oxide layer, and a second silicon substrate. The oxide layer is disposed on the first silicon substrate. The second silicon substrate is disposed on the oxide layer, in which the second silicon substrate has a thickness between 10 nm and 10 μm. An epitaxial layer is formed on the second silicon substrate.

In some embodiments, receiving the composite substrate includes the following operations. The oxide layer is formed on the first silicon substrate or the second silicon substrate. When the oxide layer is formed on the first silicon substrate, the second silicon substrate is bonded with the oxide layer. When the oxide layer is formed on the second silicon substrate, the first silicon substrate is bonded with the oxide layer. The second silicon substrate is thinned.

In some embodiments, receiving the composite substrate includes the following operations. A first oxide layer is formed on the first silicon substrate. A second oxide layer is formed on the second silicon substrate. The first oxide layer is bonded with the second oxide layer. The second silicon substrate is thinned.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiment, with reference made to the accompanying drawings as follows:

FIG. 1 is a method of forming a semiconductor substrate according to some embodiments of the present disclosure.

FIG. 2 to FIG. 4 are schematic cross-sectional views of a semiconductor substrate at different formation stages according to some embodiments of the present disclosure.

### DETAILED DESCRIPTION

Reference will now be made in detail to the present embodiments of the, examples of which are illustrated in the accompanying drawings. Wherever possible, the same reference numbers are used in the drawings and the description to refer to the same or like parts.

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

Although below using a series of operations or steps described in this method disclosed, but the order of these operations or steps shown should not be construed to limit the present invention. For example, certain operations or steps may be performed in different orders and/or concurrently with other steps. Moreover, not all steps must be performed in order to achieve the depicted embodiment of the present invention. Furthermore, each operation or procedure described herein may contain several sub-steps or actions.

In the semiconductor manufacturing process, the semiconductor substrate can be formed by directly bonding the handle wafer and the device wafer, and then the device wafer is processed to form a device layer. Subsequently, an epitaxial layer is formed on the device layer.

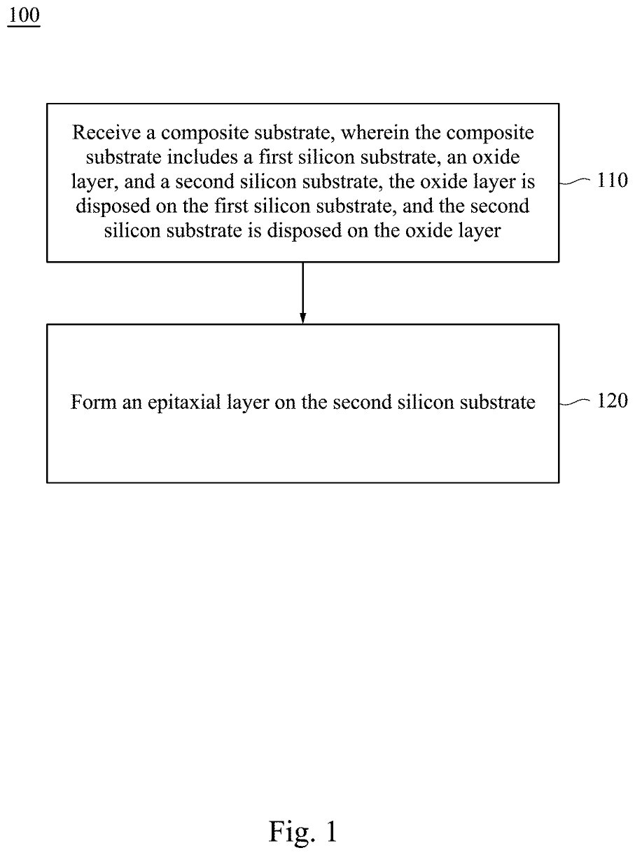

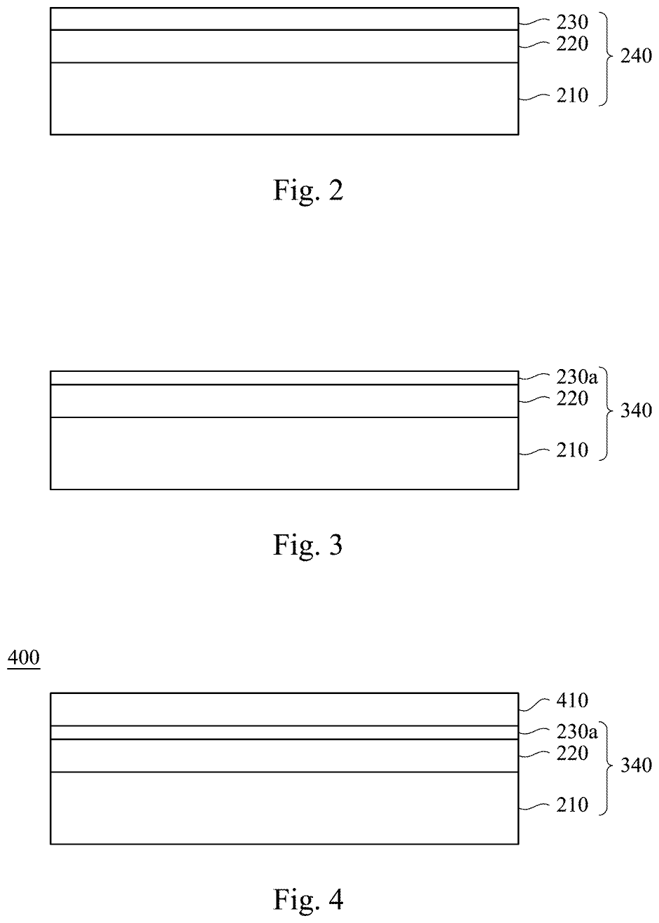

The present disclosure provides a method for forming a semiconductor substrate. Please refer to FIG. 1 to FIG. 4. FIG. 1 shows a method 100 for forming a semiconductor substrate according to some embodiments of the present disclosure. The method 100 includes an operation 110 and an operation 120. FIG. 2 to FIG. 4 are schematic cross-sectional views of a semiconductor substrate at different formation stages according to some embodiments of the present disclosure.

Please refer to FIG. 1 to FIG. 3. In some embodiments, in operation 110, as shown in FIG. 2, a composite substrate 240 is received. The composite substrate 240 includes a first silicon substrate 210, an oxide layer 220, and a second silicon substrate 230. The oxide layer 220 is disposed on the first silicon substrate 210. The second silicon substrate 230 is disposed on the oxide layer 220. The second silicon substrate 230 is thinned to form a composite substrate 340 as shown in FIG. 3. After the second silicon substrate 230 shown in FIG. 2 is thinned, the second silicon substrate 230a shown in FIG. 3 is formed. In some embodiments, receiving the composite substrate 240 includes the following operations. The oxide layer 220 is formed on the first silicon substrate 210. The second silicon substrate 230 is bonded with the oxide layer 220. In other embodiments, receiving the composite substrate 240 includes the following operations. The oxide layer 220 is formed on the second silicon substrate 230. The first silicon substrate 210 is bonded with the oxide layer 220. In other embodiments, receiving the composite substrate 240 includes the following operations. A first oxide layer (not shown) is formed on the first silicon substrate 210. A second oxide layer (not shown) is formed on the second silicon substrate 230. The first oxide layer is bonded with the second oxide layer. The first oxide layer and the second oxide layer together form the oxide layer 220.

In some embodiments, the second silicon substrate 230a shown in FIG. 3 has a thickness between 10 nm and 10 μm. For example, the thickness is 0.5 μm, 0.8 μm, 1 μm, 1.2 μm, 1.5 μm, 1.8 μm, atm, 2.5 μm, or 3 μm.

In some embodiments, the first silicon substrate 210 has a first resistance value, and the second silicon substrate 230 has a second resistance value, and the first resistance value is less than the second resistance value. Similarly, in some embodiments, the first silicon substrate 210 has a first resistance value, and the second silicon substrate 230a has a second resistance value, and the first resistance value is less than the second resistance value.

In some embodiments, the first silicon substrate 210 has a first resistance value between 0.0001 and 1 Ohm-cm. For example, the first resistance value is 0.0001, 0.0002, 0.0003, 0.0004, 0.0005, 0.0006, 0.0007, 0.0008, 0.0009, 0.001, 0.01, 0.02, 0.03, 0.04, or 0.05 Ohm-cm. In some embodiments, the second silicon substrate 230 and the second silicon substrate 230a have a second resistance value between 1 to 10000 Ohm-cm. For example, the second resistance value is 1000, 3000, 5000, 7000, 8000, 9000, or 10000 Ohm-cm. In some embodiments, the first silicon substrate 210 has a first resistance value between 0.0001 and 1 Ohm-cm, and the second silicon substrate 230 has a second resistance value between 1 and 10000 Ohm-cm. Similarly, in some embodiments, the first silicon substrate 210 has a first resistance value between 0.0001 and 1 Ohm-cm, and the second silicon substrate 230a has a second resistance value between 1 and 10000 Ohm-cm.

Please refer to FIG. 1 and FIG. 3. In other embodiments, in operation 110, as shown in FIG. 3, a composite substrate 340 is received. The composite substrate 340 includes the first silicon substrate 210, the oxide layer 220, and the second silicon substrate 230a. The oxide layer 220 is disposed on the first silicon substrate 210. The second silicon substrate 230a is disposed on the oxide layer 220.

Please refer to FIG. 1 and FIG. 4. In operation 120, an epitaxial layer 410 is formed on the second silicon substrate 230a. In other words, the epitaxial layer 410 is formed on the composite substrate 340. In some embodiments, the method of forming the epitaxial layer 410 includes, but is not limited to, a chemical vapor deposition (CVD) epitaxy process or a molecular beam epitaxy (MBE) process. In some embodiments, the epitaxial layer 410 includes, but is not limited to, gallium nitride, gallium phosphide, gallium arsenide, indium phosphide, indium gallium phosphide, indium gallium antimonide, or a combination thereof.

Please continue to refer to FIG. 4. The present disclosure provides a semiconductor substrate 400, which includes a composite substrate 340 and an epitaxial layer 410. The composite substrate 340 includes the first silicon substrate 210, the oxide layer 220, and the second silicon substrate 230a. The oxide layer 220 is disposed on the first silicon substrate 210. The second silicon substrate 230a is disposed on the oxide layer 220. In some embodiments, the second silicon substrate 230a has a thickness between 10 nm and 10 μm. For example, the thickness is 0.5 μm, 0.8 μm, 1 μm, 1.2 μm, 1.5 μm, 1.8 μm, 2 μm, 2.5 μm, or 3 μm. The epitaxial layer 410 is disposed on the second silicon substrate 230a.

It is worth noting that when the thickness of the second silicon substrate 230a is thinner, the composite substrate 340 is also thinner, and therefore the stress caused by the epitaxial layer 410 on the composite substrate 340 will be smaller. In other words, the epitaxial layer 410 causes less stress on the second silicon substrate 230a.

Please continue to refer to FIG. 4. In some embodiments, the first silicon substrate 210 has a first resistance value, and the second silicon substrate 230a has a second resistance value, and the first resistance value is less than the second resistance value. In some embodiments, the first silicon substrate 210 has a first resistance value between 0.0001 and 0.05 Ohm-cm. For example, the first resistance value is 0.0001, 0.0002, 0.0003, 0.0004, 0.0005, 0.0006, 0.0007, 0.0008, 0.0009, 0.001, 0.01, 0.02, 0.03, 0.04, or 0.05 Ohm-cm. In some embodiments, the second silicon substrate 230a has a second resistance value between 1000 and 10000 Ohm-cm. For example, the second resistance value is 1000, 3000, 5000, 7000, 8000, 9000, or 10000 Ohm-cm. When the first silicon substrate 210 has a low resistance value, the composite substrate 340 has higher mechanical strength and can resist the stress caused by the epitaxial layer 410, thereby improving the quality of the epitaxial layer 410, reducing defects caused by the epitaxial layer, and further preventing the semiconductors substrate 400 from warping and breaking.

In some embodiments, the first silicon substrate 210 is a heavily doped chip. In some embodiments, the material of the first silicon substrate 210 includes boron, phosphorus, arsenic, antimony, or a combination thereof. When the concentration of dopants in the first silicon substrate 210 is higher, the resistance value of the first silicon substrate 210 is lower.

In some embodiments, the epitaxial layer 410 includes gallium nitride, gallium phosphide, gallium arsenide, indium phosphide, indium gallium phosphide, indium gallium antimonide, or a combination thereof. In some embodiments, the epitaxial layer 410 is a gallium nitride epitaxial layer.

In some embodiments, silicon substrates with different crystal orientations can be selected as the first silicon substrate 210 according to design requirements. For example, the crystal orientation of the first silicon substrate 210 is (100), but it is not limited thereto. In some embodiments, silicon substrates with different crystal orientations can be selected as the second silicon substrate 230a according to design requirements. For example, the crystal orientation of the second silicon substrate 230a is (111), but it is not limited thereto.

The semiconductor substrate of the present disclosure includes a composite substrate and an epitaxial layer. The composite substrate includes a first silicon substrate, an oxide layer, and a second silicon substrate. The second silicon substrate has a thickness between 10 nm and 10 μm. Since the thickness of the second silicon substrate is relatively thin, the stress caused by the epitaxial layer to the composite substrate is relatively small, which makes the quality of the epitaxial layer better. Therefore, the semiconductor substrate of the present disclosure has the characteristic of not being easily warped.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor substrate, comprising:
a first silicon substrate;
an oxide layer disposed on the first silicon substrate;
a second silicon substrate disposed on the oxide layer, wherein the second silicon substrate has a thickness between 10 nm and 10 μm; and
an epitaxial layer disposed on the second silicon substrate.

2. The semiconductor substrate of claim 1, wherein the first silicon substrate has a first resistance value, the second silicon substrate has a second resistance value, and the first resistance value is less than the second resistance value.

3. The semiconductor substrate of claim 1, wherein the first silicon substrate has a first resistance value between 0.0001-1 Ohm-cm.

4. The semiconductor substrate of claim 1, wherein the second silicon substrate has a second resistance value between 1-10000 Ohm-cm.

5. The semiconductor substrate of claim 4, wherein the first silicon substrate has a first resistance value between 0.0001-1 Ohm-cm.

6. The semiconductor substrate of claim 1, wherein the first silicon substrate is a heavily doped chip.

7. The semiconductor substrate of claim 1, wherein the epitaxial layer comprises gallium nitride, gallium phosphide, gallium arsenide, indium phosphide, indium gallium phosphide, indium gallium antimonide, or a combination thereof.

8. A method of forming a semiconductor substrate, comprising:
receiving a composite substrate, wherein the composite substrate comprises a first silicon substrate, an oxide layer, and a second silicon substrate, the oxide layer is disposed on the first silicon substrate, the second silicon substrate is disposed on the oxide layer, and the second silicon substrate has a thickness between 10 nm and 10 μm; and
forming an epitaxial layer on the second silicon substrate.

9. The method of claim 8, wherein receiving the composite substrate comprises the following operations:
forming the oxide layer on the first silicon substrate or the second silicon substrate;
when forming the oxide layer on the first silicon substrate, bonding the second silicon substrate with the oxide layer, or when forming the oxide layer on the second silicon substrate, bonding the first silicon substrate with the oxide layer; and
thinning the second silicon substrate.

10. The method of claim 8, wherein receiving the composite substrate comprises the following operations:
forming a first oxide layer on the first silicon substrate;
forming a second oxide layer on the second silicon substrate;
bonding the first oxide layer with the second oxide layer; and
thinning the second silicon substrate.
